(19) United States
(12) Patent Application Publication
(10) Pub. No.: US 2008/0157229 A1
(43) Pub. Date: Jul. 3, 2008

(54) Semiconductor Device and Fabricating Method Thereof

(76) Inventor: JONG WON SUN, Gokseong-gun (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/859,900

(22) Filed: Sep. 24, 2007

(30) Foreign Application Priority Data
Dec. 28, 2006 (KR) 10-2006-0135796

(51) Int. Cl. H01L 21/47; H01L 29/76

(52) U.S. Cl. 257/410; 438/781; 257/E21.492; 257/E29.226

(57) ABSTRACT

A semiconductor device and a fabricating method thereof are provided. The method includes forming a Tetraethyl Orthosilicate (TEOS) layer on a semiconductor substrate, and performing a heat treatment on the TEOS layer to shrink the LEOS layer, thereby forming a gate oxide layer of a shrunken TEOS layer.

### CROSS-REFERENCE TO RELATED APPLICATION

The present application claims the benefit under 35 U.S.C. §119 of Korean Patent Application No. 10-2006-0135796, filed Dec. 28, 2006, which is hereby incorporated by reference in its entirety.

### BACKGROUND

The thickness of a gate oxide is a very important factor in determining device characteristics of high voltage devices. In general, the thickness of a gate oxide is increased as the voltage of a device increases. Gate oxides are often formed to a thickness in the range of several tens of angstroms to several thousands of angstroms. Gate oxides are typically formed through an oxidation process by injecting oxygen into a furnace containing the device.

Due to the fact that the thickness of gate oxides should be increased as the operating voltage level of devices increases, the oxidation time in the furnace also increases. This causes the total process time to be very long and decreases overall production capacity.

### BRIEF SUMMARY

Embodiments of the present invention provide a semiconductor device and a fabricating method thereof that can improve device characteristics and reduce fabricating time by forming a gate oxide stably and effectively.

A semiconductor device according to an embodiment of the present invention includes a semiconductor substrate and a gate oxide layer having a Tetraethyl Orthosilicate (TEOS) layer on the semiconductor substrate.

A method of fabricating a semiconductor device according to an embodiment of the present invention includes forming a TEOS layer on a semiconductor substrate and performing a heat treatment on the TEOS layer to shrink the TEOS layer, thereby forming a gate oxide layer formed of a TEOS layer.

### BRIEF DESCRIPTION OF THE DRAWINGS

FIGS. 1 and 2 are cross-sectional views illustrating a method of fabricating a semiconductor device according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

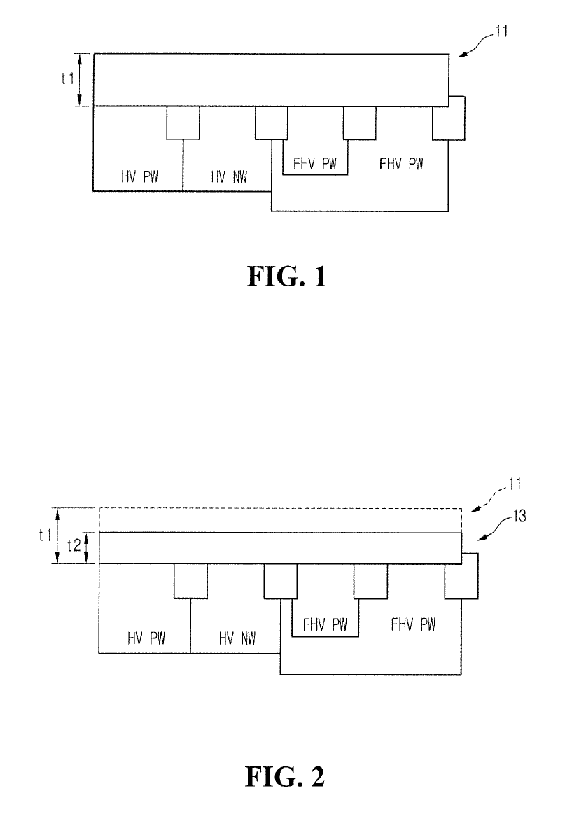

Referring to FIG. 1, according to an embodiment of the present invention, a Tetraethyl Orthosilicate (TEOS) layer 11 is formed on a semiconductor substrate. As illustrated, the semiconductor substrate can include well regions and isolation layers.

The TEOS layer 11 can be formed to a first thickness t1.

In an embodiment: the TEOS layer 11 can be formed using low pressure chemical vapor deposition (LPCVD). For example, the TEOS layer 11 can be formed at a temperature ranging from about 650° C. to about 700° C.

Then, referring to FIG. 2, a heat treatment can be performed on the resultant structure so that the TEOS layer 11 having a first thickness t1 shrinks to form a TEOS layer 13 having a second thickness t2.

In an embodiment, the TEOS layer 13 having a second thickness t2 can be formed by performing an annealing process on the TEOS layer 11.

According to the present invention, the second thickness t2 of the TEOS layer 13 is smaller than the first thickness t1 of the TEOS layer 11.

In many embodiments, the heat treatment process performed on the TEOS layer 11 having a first thickness t1 can cause the TEOS layer 13 having a second thickness t2 to be formed much denser than the TEOS layer 11 having a first thickness t1. In an embodiment, the heat treatment process is an annealing process performed at about 900° C.

The process to form the TEOS layer 11 having a first thickness t1 can be performed in the same chamber as the heat treatment process to form the TEOS layer 13 having a second thickness t2.

In embodiments where the TEOS forming process and the heat treatment process are performed in the same chamber, the process time can be greatly reduced.

The TEOS layer 13 having a second thickness t2 can be formed such that its density is high enough to be adapted for high voltage devices.

In many embodiments of the present invention, a gate oxide layer can be formed of TEOS using an LPCVD process instead of a typical furnace oxidation process. Therefore, the process time can be reduced, leading to improved fabricating capacity. In addition, the density of the TEOS layer can be improved since the TEOS can be deposited and then annealed in the same LPCVD apparatus.

While typical existing oxidation processes take a long time to form a gate oxide layer of a thickness suitable for a high voltage device, the method according to an embodiment of the present invention allows a gate oxide to be formed more quickly, thus increasing fabricating capacity.

According to an embodiment, a TEOS oxide is formed by using an LPCVD process in which the temperature of the LPCVD chamber rises up to about 900° C. Then, an annealing process can be performed to shrink the TEOS oxide.

The TEOS that has been shrunk can be formed such that its density is substantially similar to that of an oxide formed by a typical furnace oxidation process. This shrunken TEOS can be used as an insulator of a gate oxide layer.

In many embodiments, since a depositing process of TEOS and an annealing process of the deposited TEOS are performed in the same chamber, the process time can be significantly less than that of a typical furnace oxidation process.

Accordingly, according to many embodiments, the fabricating capacity of devices can be considerably increased.

Furthermore, the present invention allows for a gate oxide to be stably and effectively formed, making it possible to improve device characteristics and reduce fabricating time.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a semiconductor device, the method comprising:
forming a Tetraethyl Orthosilicate (TEOS) layer having a first thickness on a semiconductor substrate; and
performing a heat treatment process on the TEOS layer to shrink the TEOS layer having the first thickness into a TEOS layer having a second thickness, thereby forming a gate oxide layer.

2. The method according to claim 1, wherein the TEOS layer having the first thickness is formed using a low pressure chemical vapor deposition (LPCVD) process.

3. The method according to claim 2, wherein the TEOS layer having the first thickness is formed at a temperature in the range of from about 650° C. to about 700° C.

4. The method according to claim 1, wherein the heat treatment process is an annealing process.

5. The method according to claim 4, wherein the annealing process is performed at about 900° C.

6. The method according to claim 1, wherein the TEOS layer having the second thickness is denser than the TEOS layer having the first thickness.

7. The method according to claim 1, wherein the step of forming a TEOS layer having a first thickness and the step of performing a heat treatment process are carried out in the same chamber.

8. The method according to claim 1, wherein the second thickness is smaller than the first thickness.

9. A semiconductor device, comprising:
a semiconductor substrate; and
a gate oxide layer on the substrate, the gate oxide layer comprising Tetraethyl Orthosilicate (TEOS).

10. The semiconductor device according to claim 9, wherein the TEOS of the gate oxide layer is a dense TEOS layer.

11. The semiconductor device according to claim 9, wherein the TEOS of the gate oxide layer is a shrunken deposited TEOS layer.
